(19) United States
(12) Patent Application Publication
(10) Pub. No.: US 2024/0302749 A1
(43) Pub. Date: Sep. 12, 2024

(54) RESIN, AND ARF DRY PHOTORESIST COMPOSITION COMPRISING SAME AND APPLICATION

(71) Applicants: SHANGHAI SINYANG SEMICONDUSTOR MATERIALS CO., LTD., Shanghai (CN); CHINA ADVANCED LITHOGRAPHIC MATERIAL TECHNOLOGY CO. LTD., Shanghai (CN)

(72) Inventors: Su WANG, Shanghai (CN); Shunong FANG, Shanghai (CN); Sen XU, Shanghai (CN); Yiming LIN, Shanghai (CN)

(21) Appl. No.: 18/637,481

(22) Filed: Apr. 17, 2024

Related U.S. Application Data
(63) Continuation-in-part of application No. PCT/CN2021/134376, filed on Nov. 30, 2021.

(30) Foreign Application Priority Data
Oct. 26, 2021 (CN) 202111245391.X

(51) Int. Cl. G03F 7/20; G03F 7/004

(52) U.S. Cl. CPC G03F 7/2006; G03F 7/0045; G03F 7/0048

(57) ABSTRACT

A resin, and an ArF dry photoresist composition comprising same and an application. The resin is obtained by polymerizing the following monomers in parts by weight: 40-47.5 parts of a monomer (A), 0.5-5 parts of a monomer (B), 0.25-2.5 parts of a monomer (C), and 0.25-2.5 parts of a monomer (D). A photoresist comprising the resin has the advantages of being high in resolution, high in sensitivity, and low in line width roughness.

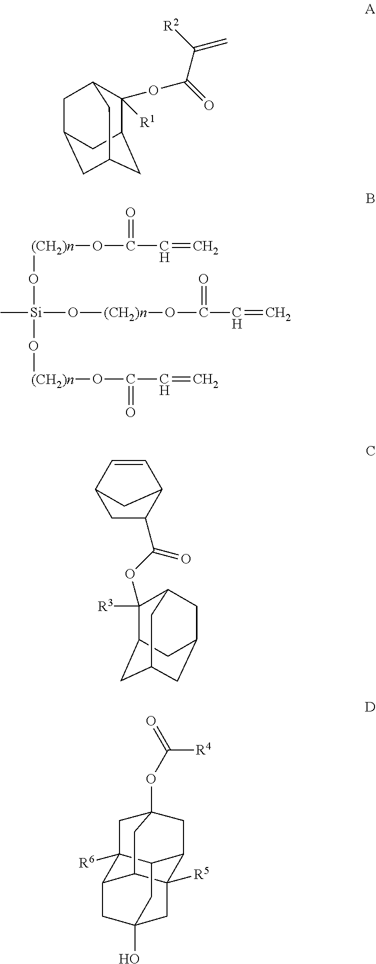

### CROSS-REFERENCE TO RELATED APPLICATIONS

The application is a Continuation-in-part application of International Application No. PCT/CN2021/134376, filed on Nov. 30, 2021, which claims the priority of Chinese patent application No. 202111245391X filed on Oct. 26, 2021, the contents of which are incorporated herein by reference in their entireties.

### TECHNICAL FIELD

The present disclosure relates to a resin and an ArF dry photoresist composition containing same, and use thereof.

### BACKGROUND

Lithography refers to a pattern micromachining technique that transfers a pattern designed on a mask onto a substrate by means of exposure, development, etching and other processes using the chemical sensitivity of a lithographic material (specifically a photoresist) under the action of visible light, ultraviolet light, electron beams, etc. A lithographic material (specifically a photoresist), also known as a photoresist, is the most critical functional chemical material involved in lithography, the main components thereof being a resin, a photo acid generator (PAG), and corresponding additives and solvents. A photoacid generator is a photosensitive compound, which is decomposed under the illumination to produce an acid, and the acid thus produced can allow a decomposition or cross-linking reaction of an acid-sensitive resin, thereby increasing the dissolution contrast between an illuminated portion and a non-illuminated portion in a developing solution and being applicable to the technical field of pattern micromachining.

The three important parameters of a photoresist, including resolution, sensitivity and line width roughness, determine the process window of the photoresist during chip manufacturing. With the continuous improvement of the performance of semiconductor chips, the integration level of integrated circuits increases exponentially, and patterns in integrated circuits become smaller and smaller. In order to fabricate smaller patterns, it is necessary to improve the above-mentioned three performance indexes of a photoresist. According to the Rayleigh equation, the resolution of a photoresist can be improved by using a short-wavelength light source in a photolithography process. The wavelength of a light source used in a photolithography process has developed from 365 nm (I-line) to 248 nm (KrF), 193 nm (ArF) and 13 nm (EUV). In order to improve the sensitivity of a photoresist, a chemically amplified photosensitive resin is currently used in mainstream KrF, ArF and EUV photoresists. Therefore, a photoacid generator matched with a chemically amplified photosensitive resin is widely used in high-end photoresists.

With the gradual development of a photolithography process to a 193-nm dry exposure process, the complexity of the process increases, and there are increasingly higher requirements on a resist (i.e. photoresist). It has become an urgent problem to be solved in the industry to develop a resist that can improve the resolution, sensitivity and line width roughness of a photoresist.

### CONTENT OF THE PRESENT INVENTION

The technical problem addressed by the present disclosure is to overcome the deficiency of limited resin types available for use in photoresists. To this end, provided are a resin, and an ArF dry photoresist composition containing same, and use thereof. The photoresist containing a resin of the present disclosure has the advantages of high resolution, high photosensitivity, and low line width roughness.

The present disclosure provides a resin obtained by the following polymerizing monomers in parts by weight: 40 to 47.5 parts of monomer A, 0.5 to 5 parts of monomer B, 0.25 to 2.5 parts of monomer C, and 0.25 to 2.5 parts of monomer D;

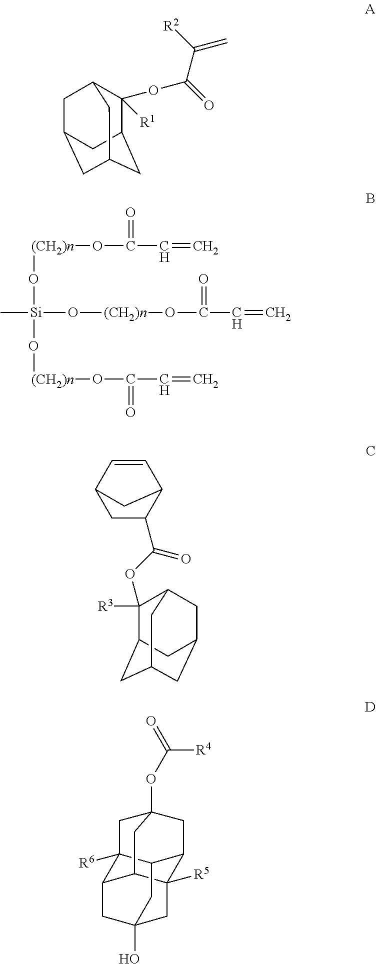

wherein R¹ is C₁₋₁₀ alkyl;
R² is H or C₁₋₁₀ alkyl;
n is 1, 2, or 3;
R³ is C₁₋₁₀ alkyl;
R⁴ is C₂₋₄ alkenyl;
R⁵ and R⁶ are independently H or C₁₋₅ alkyl;
the molecular weight distribution coefficient (Mw/Mn) of the resin is 1.5 to 2.0.

In some embodiments, for R¹, the C₁₋₁₀ alkyl is C₁₋₅ alkyl, preferably methyl, ethyl, n-propyl, isopropyl, n-butyl, sec-butyl, isobutyl, or tert-butyl, such as methyl.

In some embodiments, for R², the C₁₋₁₀ alkyl is C₁₋₅ alkyl, preferably methyl, ethyl, n-propyl, isopropyl, n-butyl, sec-butyl, isobutyl, or tert-butyl, such as methyl.

In some embodiments, for R³, the C₁₋₁₀ alkyl is C₁₋₅ alkyl, preferably methyl, ethyl, n-propyl, isopropyl, n-butyl, sec-butyl, isobutyl, or tert-butyl, such as methyl.

In some embodiments, for R⁴, the C₂₋₄ alkenyl is C₂₋₃ alkenyl, preferably ethenyl or isopropenyl, such as isopropenyl.

In some embodiments, for R⁵, the C₁₋₅ alkyl is preferably methyl, ethyl, n-propyl, isopropyl, n-butyl, sec-butyl, isobutyl, or tert-butyl, such as methyl.

In some embodiments, the n is 2.

In some embodiments, R² is C₁₋₁₀ alkyl.

In some embodiments, R⁵ and R⁶ are independently C₁₋₁₀ alkyl.

In some embodiments, the monomer A is

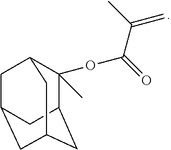 [SMILES: C=C(C)C(=O)OC1(C)C2CC3CC(C2)CC1C3]

In some embodiments, the monomer B is

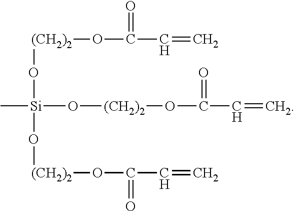

In some embodiments, the monomer Cis

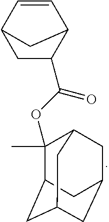 [SMILES: CC1(OC(=O)C2CC3C=CC2C3)C2CC3CC(C2)CC1C3]

In some embodiments, the monomer D is

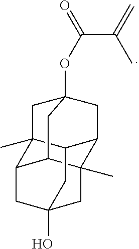 [SMILES: C=C(C)C(=O)OC12CC3C4CC5(O)CC(C(C1)C3(C)C5)C4(C)C2]

In some embodiments, the weight average molecular weight (Mw) of the resin is 5,000 to 10,000, such as 5,516 to 9,209 (e.g., 6,873, 7,199, 5,956, or 6,577).

In some embodiments, the molecular weight distribution coefficient of the resin is 1.8 to 2.0 (e.g., 1.9).

The molecular weight distribution coefficient refers to the ratio of the weight average molecular weight to the number average molecular weight of the resin.

In some embodiments, the monomer A is 42.5 to 46 parts by weight, such as 45 parts by weight.

In some embodiments, the monomer A is 42.5 to 45 parts by weight.

In some embodiments, the monomer B is 2.5 to 5 parts by weight (such as 4 parts by weight).

In some embodiments, the monomer C is 0.25 to 1.75 parts by weight (such as 0.5, 0.75, or 1.25 parts by weight).

In some embodiments, the monomer C is 0.5 to 1.25 parts by weight (such as 0.75 parts by weight).

In some embodiments, the monomer D is 0.5 to 1.75 parts by weight (such as 0.75, or 1.25 parts by weight).

In some embodiments, the monomer D is 0.5 to 1.25 parts by weight (such as 0.75 parts by weight).

In some embodiments, the monomer A is

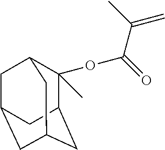 [SMILES: C=C(C)C(=O)OC1(C)C2CC3CC(C2)CC1C3]

and is 42.5 to 46 parts by weight;
the monomer B is

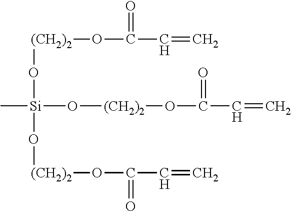

and is 2.5 to 5 parts by weight;
the monomer C is

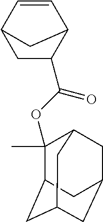 [SMILES: CC1(OC(=O)C2CC3C=CC2C3)C2CC3CC(C2)CC1C3]

and is 0.25 to 1.25 parts by weight;
the monomer D is

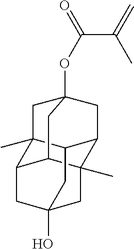 [SMILES: C=C(C)C(=O)OC12CC3C4CC5(O)CC(C(C1)C3(C)C5)C4(C)C2]

and is 0.5 to 1.75 parts by weight.

In some embodiments, the monomer A is

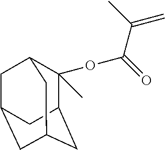 [SMILES: C=C(C)C(=O)OC1(C)C2CC3CC(C2)CC1C3]

and is 42.5 to 45 parts by weight;
the monomer B is

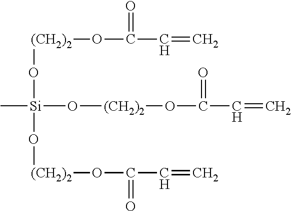

and is 2.5 to 5 parts by weight;
the monomer C is

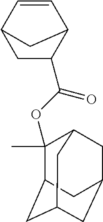 [SMILES: CC1(OC(=O)C2CC3C=CC2C3)C2CC3CC(C2)CC1C3]

and is 0.5 to 1.25 parts by weight;
the monomer D is

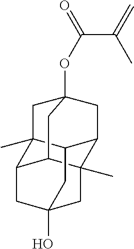 [SMILES: C=C(C)C(=O)OC12CC3C4CC5(O)CC(C(C1)C3(C)C5)C4(C)C2]

and is 0.5 to 1.25 parts by weight.

In some embodiments, the resin is any one of resins 1 to 6 obtained by polymerizing the following monomers in parts by weight:
resin 1: 42.5 parts of monomer A, 5 parts of monomer B, 1.25 parts of monomer C, and 1.25 parts of monomer D; with a weight-average molecular weight of 6,873 and a molecular weight distribution coefficient of 2;
resin 2: 45 parts of monomer A, 4 parts of monomer B, 0.5 parts of monomer C, and 0.5 parts of monomer D; with a weight-average molecular weight of 9,209 and a molecular weight distribution coefficient of 1.8;
resin 3: 45 parts of monomer A, 4 parts of monomer B, 0.25 parts of monomer C, and 0.75 parts of monomer D; with a weight-average molecular weight of 7,199 and a molecular weight distribution coefficient of 2;
resin 4: 45 parts of monomer A, 2.5 parts of monomer B, 1.25 parts of monomer C, and 1.25 parts of monomer D; with a weight-average molecular weight of 5,956 and a molecular weight distribution coefficient of 1.9;
resin 5: 42.5 parts of monomer A, 4 parts of monomer B, 1.75 parts of monomer C, and 1.75 parts of monomer D; with a weight-average molecular weight of 6,577 and a molecular weight distribution coefficient of 2;
resin 6: 46 parts of monomer A, 2.5 parts of monomer B, 0.75 parts of monomer C, and 0.75 parts of monomer D; with a weight-average molecular weight of 5,516 and a molecular weight distribution coefficient of 1.5;
in the resins 1 to 6, the monomer A is

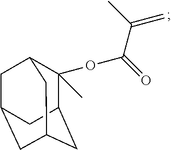 [SMILES: C=C(C)C(=O)OC1(C)C2CC3CC(C2)CC1C3]

the monomer B is

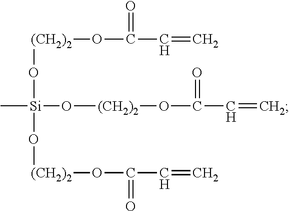

the monomer C

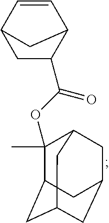 [SMILES: CC1(OC(=O)C2CC3C=CC2C3)C2CC3CC(C2)CC1C3]

is the monomer D is

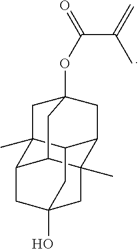 [SMILES: C=C(C)C(=O)OC12CC3C4CC5(O)CC(C(C1)C3(C)C5)C4(C)C2]

In the resin 1, the weight average molecular weight of the resin can be 6873; the molecular weight distribution coefficient of the resin can be 2.

In the resin 2, the weight average molecular weight of the resin can be 9209; the molecular weight distribution coefficient of the resin can be 1.8.

In the resin 3, the weight average molecular weight of the resin can be 7199; the molecular weight distribution coefficient of the resin can be 2.

In the resin 4, the weight average molecular weight of the resin can be 5956; the molecular weight distribution coefficient of the resin can be 1.9.

In the resin 5, the weight average molecular weight of the resin can be 6577; the molecular weight distribution coefficient of the resin can be 2.

In the resin 6, the weight average molecular weight of the resin can be 5516; the molecular weight distribution coefficient of the resin can be 1.5.

The present disclosure further provides a preparation method for the resin, the preparation method comprising the following steps: carrying out a polymerization reaction involving the monomer A in 40 to 47.5 parts by weight, the monomer B in 0.5 to 5 parts by weight, the monomer C in 0.25 to 2.5 parts by weight, and the monomer D in 0.25 to 2.5 parts by weight in an organic solvent to obtain the resin;

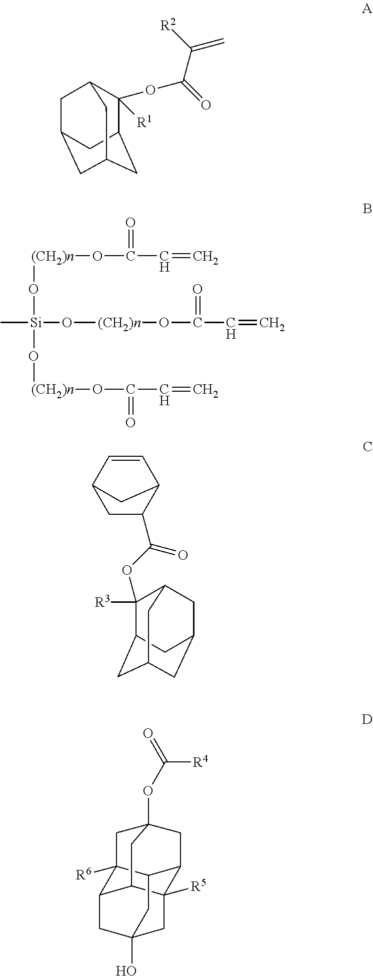

R¹, R², R³, R⁴, R⁵, R⁶, and n are as previously defined;

The amount of the monomer A, the monomer B, the monomer C, and the monomer D are as previously described.

The conditions and operations for the polymerization reaction can be those conventional for such reactions in this field. The present disclosure particularly prefers the following conditions and operations:
in the polymerization reaction, the total weight of the monomer A, the monomer B, the monomer C, and the monomer D to the weight of the organic solvent is preferably in the ratio of 0.40:1 to 1.2:1, such as 0.47:1 or 0.50:1.

In the polymerization reaction, the organic solvent is preferably one or more than one of aromatic solvents (e.g., toluene or benzene), ether solvents (e.g., tetrahydrofuran (THF), ether, or dioxane), methyl ethyl ketone (MEK), propylene glycol monomethyl ether acetate (PGMEA), and γ-butyrolactone, such as propylene glycol monomethyl ether acetate.

The polymerization reaction is preferably initiated in the presence of a free radical initiator or by heating, such as by heating.

When the polymerization reaction is initiated in the presence of a free radical initiator, the free radical initiator is preferably one or more than one of 2,2′-azobisisobutyronitrile (AIBN), 2,2′-azobis(2,4-dimethylvaleronitrile), dimethyl 2,2′-azobis(2-methylpropionate), benzoyl peroxide, and lauroyl peroxide.

When the polymerization reaction is initiated by heating, in the polymerization reaction, the temperature of the polymerization reaction is preferably 50 to 150° C., more preferably 60 to 100° C., such as 70° C.

In the polymerization reaction, the duration of the polymerization reaction is preferably 2 to 6 hours, for example, 3 hours.

Preferably, the polymerization reaction comprises the following steps:
step 1: mixing the monomer A, the monomer B, the monomer C, and the monomer D with propylene glycol monomethyl ether acetate to obtain a mixture;
the total weight of monomers A, B, C, and D to the weight of propylene glycol monomethyl ether acetate is in the ratio of 0.65:1 to 0.75:1 (such as 0.67:1 or 0.71:1);
step 2: polymerizing the mixture obtained in step 1 in propylene glycol monomethyl ether acetate to obtain the resin;
the weight of the mixture to the weight of propylene glycol monomethyl ether acetate is in the ratio of 3:1 to 5:1 (such as 4:1); the polymerization temperature is 60 to 100° C. (such as 70° C.).

In step 2, it is preferable to add the mixture obtained in step 1 to propylene glycol monomethyl ether acetate for polymerization by dropwise addition (dropwise addition rate of 20 to 40 g/hour, such as 30 g/hour).

In the polymerization reaction, for the purpose of molecular weight control, any known chain transfer agents (e.g., dodecanethiol or 2-mercaptoethanol) can be added. The amount of the chain transfer agent added is preferably 0.01 to 10 mol % (the amount of the chain transfer agent can be calculated based on the total molar amount of the monomers to be polymerized).

After the completion of the polymerization reaction, the preferred post-treatment steps for the reaction are as follows: cooling, precipitating the solid (such as by adding methanol to precipitate the solid), filtering, and drying (such as vacuum drying at 40° C. for 24 hours).

The present disclosure further provides a resin prepared by the preparation method as described above.

The present disclosure further provides a photoresist composition prepared from the following raw materials comprising the following components in parts by weight: 75 to 95 parts of a resin, 1.0 to 10 parts of a photoacid generator, 1,000 to 2,000 parts of a solvent, 0.5 to 3.0 part of a quencher, and a surfactant;
the resin is the aforementioned resin or a resin prepared by the aforementioned method of preparing the resin.

In the photoresist composition, the resin is preferably 85 to 95 parts by weight, such as 90 parts by weight.

In the photoresist composition, the resin is preferably resin 1.

In the photoresist composition, the photoacid generator is preferably 3 to 10 parts by weight, such as 5 or 7 parts by weight.

In the photoresist composition, the photoacid generator can be any conventionally used photoacid generator in the art, and preferably is a compound of formula (I):
wherein X⁺ is

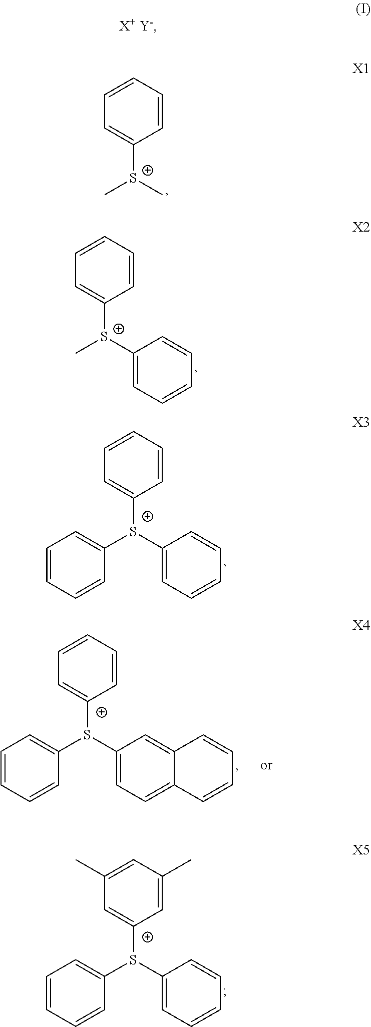

Y⁻ is

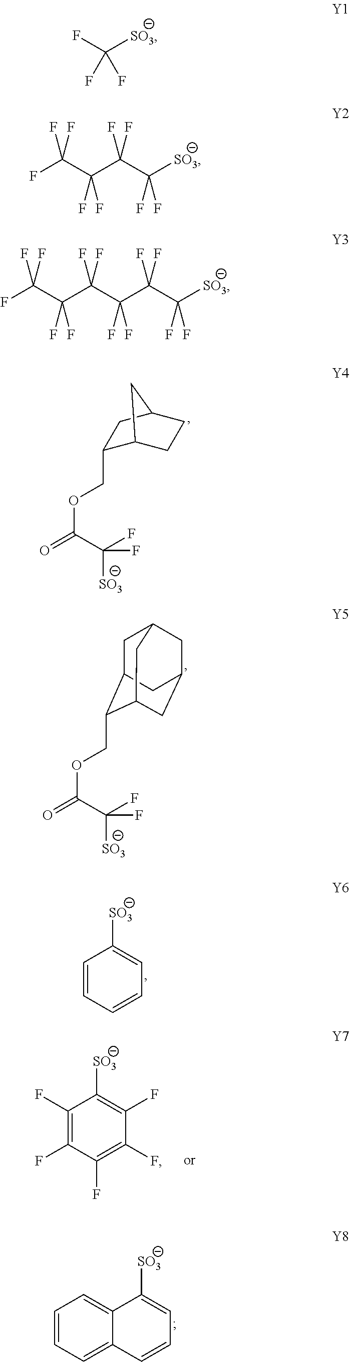

and further preferably is one or more than one of

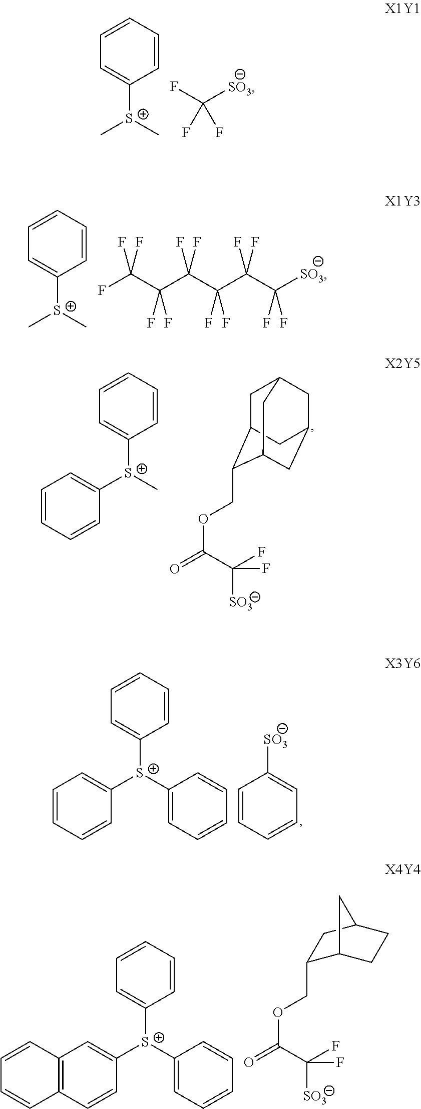

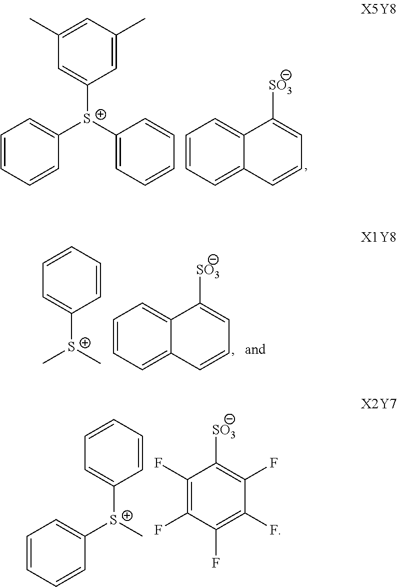

In the photoresist composition, the solvent is preferably 1,200 to 1,600 parts by weight, such as 1,500 or 1,600 parts by weight.

In the photoresist composition, the solvent can be any known photoacid generator conventionally used in photoresists, especially in chemically amplified photoresist compositions. The solvent can be one or more than one of ketone solvent (e.g., cyclohexanone and/or methyl-2-pentanone), monohydric alcohol solvent (e.g., monohydric alcohol (e.g., 3-methoxybutanol, 3-methyl-3-methoxybutanol, 1-methoxy-2-propanol, and 1-ethoxy-2-propanol), dihydric alcohol solvent (e.g., diacetone alcohol)), ether solvent (e.g., one or more than one of propylene glycol monomethyl ether, ethylene glycol monomethyl ether, propylene glycol monoethyl ether, ethylene glycol monoethyl ether, propylene glycol dimethyl ether, and diethylene glycol dimethyl ether), and ester solvent (e.g., one or more than one of propylene glycol monomethyl ether acetate (PGMEA), propylene glycol monoethyl ether acetate, methyl lactate, ethyl pyruvate, butyl acetate, 3-methoxypropyl acetate, 3-ethoxypropyl acetate, tert-butyl acetate, tert-butyl propionate, propylene glycol monobutyl ether acetate, and γ-butyrolactone).

More preferably, the solvent can be one or more than one of ketone solvent, ether solvent, and ester solvent, such as one or more than one of cyclohexanone, ethylene glycol monoethyl ether, and γ-butyrolactone.

In the photoresist composition, the quencher is preferably 0.8 to 2 parts by weight, such as 1.5 parts by weight.

In the photoresist composition, the quencher can be any conventionally used quenchers in the art, preferably one or more than one of amine compound (primary, secondary, and tertiary amine compounds, specifically those having hydroxyl, ether, ester, lactone, cyano, or sulfonate ester groups), sulfonate, and carboxylate, more preferably sulfonate, further preferably a compound of formula Q1 and/or formula Q2, still more preferably a compound of formula Q1;

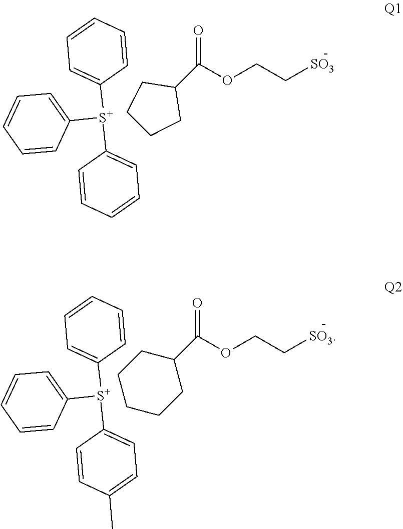

Especially when the photoresist composition further contains alkali-labile components, it is effective to use amine compounds for protection.

In the photoresist composition, the amount of surfactant can be within the conventional range used in those photoresists in the art, with the preferred amount 0.1 to 0.2 parts by weight, such as 0.15 parts.

In the photoresist composition, the surfactant can be any conventionally used surfactant that is insoluble or substantially insoluble in water but soluble in an alkaline developer, and/or that is insoluble or substantially insoluble in both water and an alkaline developer in the art, preferably one or more than one of FC-4430 (purchased from 3M), S-381 (purchased from AGC Seimi Chemical), E1004 (purchased from Air Products), KH-20, and KH-30 (purchased from Asahi Glass), more preferably KH-20 and/or KH-30, still more preferably KH-30.

In some embodiments, in the photoresist composition, the photoacid generator is one or more than one of

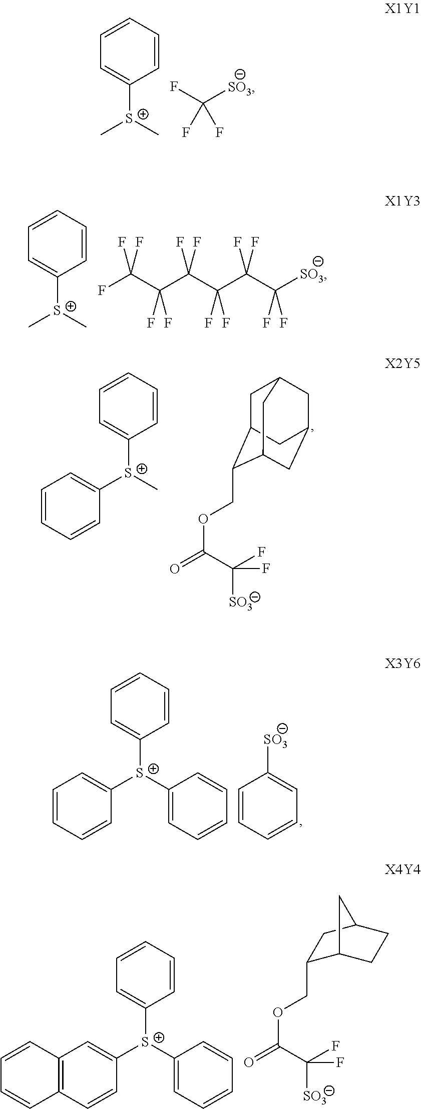

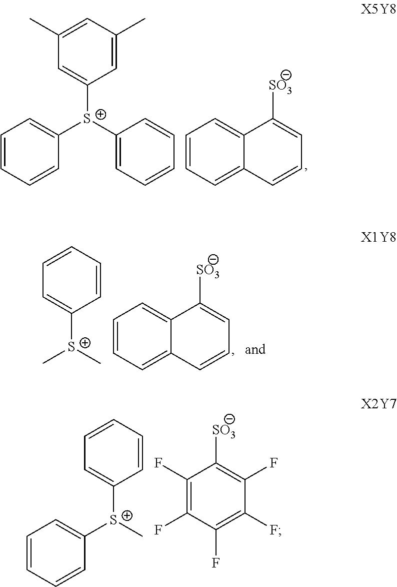

the solvent can be one or more than one of cyclohexanone (S1), ethylene glycol monoethyl ether (S2), and γ-butyrolactone (S3);
the quencher is

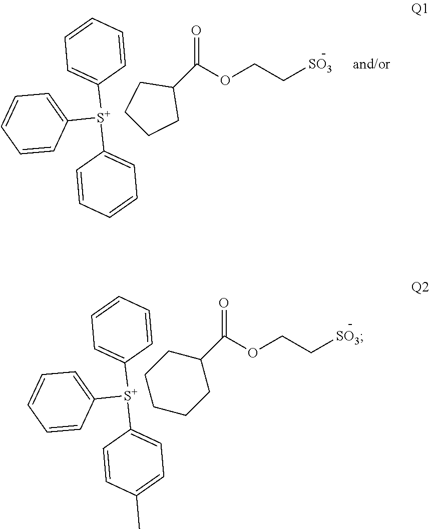

the surfactant is KH-20 and/or KH-30;
preferably, the resin is resin 1;
the quencher is

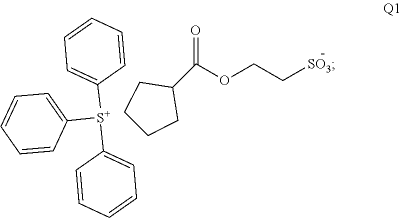

the surfactant is KH-30.

In some embodiments, the photoresist composition is prepared from the following raw materials comprising the following components in parts by weight: the resin as described above (including types and amounts of the resin), the photoacid generator as described above (including types and amounts of the photoacid generator), the solvent as described above (including types and amounts of the solvent), the quencher as described above (including types and amounts of the quencher), and the surfactant as described above (including types and amounts of the surfactant).

In some embodiments, the photoresist composition is any one of the following photoresist compositions prepared from the following raw materials in parts by weight:
photoresist composition 1: 85 parts of resin 1, 7 parts of the compound of formula X1YI, 1,500 parts of cyclohexanone (S1), 2 parts of the compound of formula Q1, and 0.15 parts of KH-30;
photoresist composition 2: 75 parts of resin 1, 1 part of the compound of formula X1YI, 1,000 parts of cyclohexanone (S1), 0.5 parts of the compound of formula Q1, and 0.1 parts of KH-30;
photoresist composition 3: 80 parts of resin 1, 3 parts of the compound of formula X1YI, 1,200 parts of cyclohexanone (S1), 0.8 parts of the compound of formula Q1, and 0.12 parts of KH-30;
photoresist composition 4: 90 parts of resin 1, 5 parts of the compound of formula X1YI, 1,600 parts of cyclohexanone (S1), 1.5 parts of the compound of formula Q1, and 0.16 parts of KH-30;
photoresist composition 5: 95 parts of resin 1, 10 parts of the compound of formula X1YI, 2,000 parts of cyclohexanone, 3 parts of the compound of formula Q1, and 0.2 parts of KH-30;
photoresist composition 6: 85 parts of resin 1, 7 parts of the compound of formula X1Y3, 1,500 parts of cyclohexanone (S1), 2 parts of the compound of formula Q1, and 0.15 parts of KH-30;
photoresist composition 7: 85 parts of resin 1, 7 parts of the compound of formula X2Y5, 1,500 parts of cyclohexanone (S1), 2 parts of the compound of formula Q1, and 0.15 parts of KH-30;
photoresist composition 8: 85 parts of resin 1, 7 parts of the compound of formula X3Y6, 1,500 parts of cyclohexanone (S1), 2 parts of the compound of formula Q1, and 0.15 parts of KH-30;
photoresist composition 9: 85 parts of resin 1, 7 parts of the compound of formula X4Y4, 1,500 parts of cyclohexanone (S1), 2 parts of the compound of formula Q1, and 0.15 parts of KH-30;
photoresist composition 10: 85 parts of resin 1, 7 parts of the compound of formula X5Y8, 1,500 parts of cyclohexanone (S1), 2 parts of the compound of formula Q1, and 0.15 parts of KH-30;
photoresist composition 11: 85 parts of resin 1, 7 parts of the compound of formula X1Y8, 1,500 parts of cyclohexanone (S1), 2 parts of the compound of formula Q1, and 0.15 parts of KH-30;
photoresist composition 12: 85 parts of resin 1, 7 parts of the compound of formula X2Y7, 1,500 parts of cyclohexanone (S1), 2 parts of the compound of formula Q1, and 0.15 parts of KH-30;
photoresist composition 13: 85 parts of resin 1, 7 parts of the compound of formula X1Y1, 1,500 parts of ethylene glycol monoethyl ether (S2), 2 parts of the compound of formula Q1, and 0.15 parts of KH-30;
photoresist composition 14: 85 parts of resin 1, 7 parts of the compound of formula X1Y1, 1,500 parts of γ-butyrolactone (S3), 2 parts of the compound of formula Q1, and 0.15 parts of KH-30;
photoresist composition 15: 85 parts of resin 1, 7 parts of the compound of formula X1Y1, 1,500 parts of cyclohexanone (S1), 2 parts of the compound of formula Q2, and 0.15 parts of KH-30;
photoresist composition 16: 85 parts of resin 1, 7 parts of the compound of formula X1Y1, 1,500 parts of γ-butyrolactone (S3), 2 parts of the compound of formula Q1, and 0.15 parts of KH-20;
photoresist composition 17: 85 parts of resin 2, 7 parts of the compound of formula X1YI, 1,500 parts of cyclohexanone (S1), 2 parts of the compound of formula Q1, and 0.15 parts of KH-30;
photoresist composition 18: 85 parts of resin 3, 7 parts of the compound of formula X1YI, 1,500 parts of cyclohexanone (S1), 2 parts of the compound of formula Q1, and 0.15 parts of KH-30;
photoresist composition 19: 85 parts of resin 4, 7 parts of the compound of formula X1YI, 1,500 parts of cyclohexanone (S1), 2 parts of the compound of formula Q1, and 0.15 parts of KH-30;
photoresist composition 20: 85 parts of resin 5, 7 parts of the compound of formula X1YI, 1,500 parts of cyclohexanone (S1), 2 parts of the compound of formula Q1, and 0.15 parts of KH-30;
photoresist composition 21: 85 parts of resin 8, 7 parts of the compound of formula X1YI, 1,500 parts of cyclohexanone (S1), 2 parts of the compound of formula Q1, and 0.15 parts of KH-30;
wherein, any one of resins 1 to 6 is obtained by polymerizing the following monomers in parts by weight:
resin 1: 42.5 parts of monomer A, 5 parts of monomer B, 1.25 parts of monomer C, and 1.25 parts of monomer D; with a weight-average molecular weight of 6,873 and a molecular weight distribution coefficient of 2;
resin 2: 45 parts of monomer A, 4 parts of monomer B, 0.5 parts of monomer C, and 0.5 parts of monomer D; with a weight-average molecular weight of 9209 and a molecular weight distribution coefficient of 1.8;
resin 3: 45 parts of monomer A, 4 parts of monomer B, 0.25 parts of monomer C, and 0.75 parts of monomer D; with a weight-average molecular weight of 7199 and a molecular weight distribution coefficient of 2;
resin 4: 45 parts of monomer A, 2.5 parts of monomer B, 1.25 parts of monomer C, and 1.25 parts of monomer D; with a weight-average molecular weight of 5956 and a molecular weight distribution coefficient of 1.9;
resin 5: 42.5 parts of monomer A, 4 parts of monomer B, 1.75 parts of monomer C, and 1.75 parts of monomer D; with a weight-average molecular weight of 6577 and a molecular weight distribution coefficient of 2;
resin 6: 46 parts of monomer A, 2.5 parts of monomer B, 0.75 parts of monomer C, and 0.75 parts of monomer D; with a weight-average molecular weight of 5,516 and a molecular weight distribution coefficient of 1.5;
in the resins 1 to 6, the monomer A is

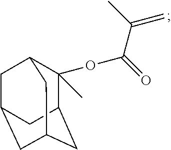 [SMILES: C=C(C)C(=O)OC1(C)C2CC3CC(C2)CC1C3]

the monomer B is

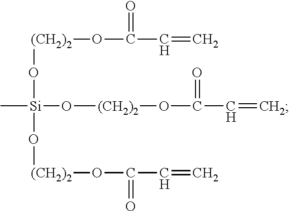

the monomer C

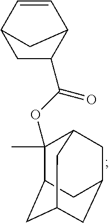 [SMILES: CC1(OC(=O)C2CC3C=CC2C3)C2CC3CC(C2)CC1C3]

is the monomer D is

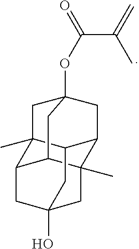 [SMILES: C=C(C)C(=O)OC12CC3C4CC5(O)CC(C(C1)C3(C)C5)C4(C)C2]

The present disclosure provides a preparation method for the photoresist composition as described above, the preparation method comprising the following steps: mixing the components of the photoresist composition as described above uniformly.

In the preparation method for the photoresist composition, after the mixing, it may further comprise a filtration step. The method of the filtration can be conventional in the art, preferably to use a filter for filtering. The pore size of the filter membrane of the filter is preferably 0.2 μm.

The present disclosure provides a use of the photoresist composition in ArF dry lithography.

The ArF dry lithography preferably comprises the following steps:
S1: coating the substrate surface with the photoresist composition as described above, and baking to form a photoresist layer;
S2: exposing the photoresist layer formed in S1;
S3: baking the exposed photoresist layer exposed in S2;
S4: developing the baked photoresist layer baked in S3.

In S1, the substrate can be a substrate for the manufacture of integrated circuits (such as one or more of Si, SiO₂, SIN, SION, TIN, WSi, BPSG, SOG, and organic anti-reflective film), or a substrate for the manufacture of mask circuits (such as one or more of Cr, CrO, CrON, MoSi₂, and SiO₂).

In S1, the method of coating can be a conventional one used in the art for forming a photolithographic pattern, such as spin coating.

In S1, the baking temperature can be a conventional one used in the art for forming a photolithographic pattern, such as 60 to 200° C.

In S1, the baking time can be a conventional one used in the art for forming a photolithographic pattern, such as 1 to 10 minutes, or such as 1 minute.

In S1, the thickness of the photoresist layer can be 0.05 to 2 μm, such as 100 nm.

In S2, the exposure can be carried out using conventional operations used in the art for forming photolithographic patterns, such as high-energy radiation (e.g., KrF excimer laser, ArF excimer laser (e.g., exposure in an ArF excimer laser stepper (Nikon Corp., NA-0.68), or EUV), wherein the dose of exposure can be 1 to 200 mJ/cm² (such as 10 to 100 mJ/cm²), or using electron beam exposure, wherein the dose of exposure can be 0.1 to 100 C/cm² (such as 0.5 to 50 μC/cm²); or, for example, by completing the exposure through an immersion lithography method that involves providing a liquid with a refractive index of at least 1.0 (such as water) between the projection lens and the photoresist layer.

In S3, the baking temperature can be those conventional used in the art for forming photolithographic patterns, such as 60 to 150° C., or such as 90 to 100° C., or such as 95° C.

In S3, the baking duration can be a conventional baking duration used in the art for forming photolithographic patterns, such as 1 to 5 minutes, or such as 1 minute.

In S4, the method of development can be a conventional method of development used in the art for forming photolithographic patterns, preferably one or more than one of immersion, spin-coating immersion, and spraying, such as spin-coating immersion.

In S4, the developer used for the development can be a conventional developer used in the art for forming photolithographic patterns, such as an alkaline aqueous solution and/or an organic solvent.

The concentration of the alkaline aqueous solution may range from 0.1 to 5 wt %, preferably 2 to 3 wt % tetramethylammonium hydroxide (TMAH) solution.

The organic solvent can be one or more than one of 2-octanone, 2-nonanone, 2-heptanone, 3-heptanone, 4-heptanone, 2-hexanone, 3-hexanone, diisobutyl ketone, methyl cyclohexanone, acetophenone, methyl acetophenone, propyl acetate, butyl acetate, isobutyl acetate, pentyl acetate, isopentyl acetate, butenyl acetate, benzyl acetate, propyl formate, butyl formate, isobutyl formate, pentyl formate, isopentyl formate, methyl valerate, methyl crotonate, methyl ricinoleate, ethyl ricinoleate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, benzyl acetate, methyl phenylacetate, benzyl formate, ethyl phenylformate, methyl 3-phenylpropionate, benzyl propionate, ethyl phenylacetate, and ethyl 2-phenylacetate.

In S4, the development temperature can be those conventional used in the art for forming photolithographic patterns, preferably 10 to 30° C., such as room temperature.

In S4, the development duration can be a conventional development duration used in the art for forming photolithographic patterns, such as 0.1 to 3 minutes, such as 0.5 to 2 minutes.

Any desired steps can be added to the pattern formation method. For example, following the formation of the photoresist layer, a step involving rinsing with pure water (post-soaking) can be introduced to extract photoacid generators or other components from the film surface or to wash away particles. After exposure, a rinsing (post-soaking) step can be introduced to remove any water remaining on the film post-exposure.

On the basis of conforming to common knowledge in the art, the above-mentioned preferred conditions can be arbitrarily combined to obtain various preferred embodiments of the present disclosure.

Reagents and raw materials used in the present disclosure are all commercially available.

The positive effects of the present disclosure lie in: the photoresist comprising the resin of the present disclosure has at least the following advantages: excellent photosensitivity, a good depth of focus (DOF), and a good critical dimension uniformity (CDU).

### DETAILED DESCRIPTION OF THE PREFERRED EMBODIMENT

The present disclosure is further described below by way of examples; however, the present disclosure is not limited to the scope of the described examples. For the experimental methods in which no specific conditions are specified in the following examples, selections are made according to conventional methods and conditions or according to the product instructions.

In the following examples, unless a specific operating temperature is defined, it is to be understood that the procedures are conducted at room temperature. Room temperature refers to the range of 10 to 30° C.

### Examples 1 to 6 and Comparative Examples 1 to 6 Preparation of Resins 1 to 6 and Comparative Resins 1 to 6

Under a nitrogen atmosphere, a solution was prepared by dissolving the following monomer A, monomer B, monomer C, monomer D in 70 g of propylene glycol monomethyl ether acetate (PGMEA) according to the parts by weight (g) in Table 1. Under a nitrogen atmosphere, this solution was then dropwise added to 30 g of propylene glycol monomethyl ether acetate (PGMEA) over 5 hours, with stirring at 70° C. After the dropwise addition is completed, stirring was continued at 70° C. for 3 hours. The reaction solution was cooled to room temperature and added dropwise to 1,000 g of methanol. The precipitated solid was collected by filtration and dried under vacuum at 40° C. for 24 hours to obtain resins 1 to 6 and comparative resins 1 to 6 in the form of powder solids.

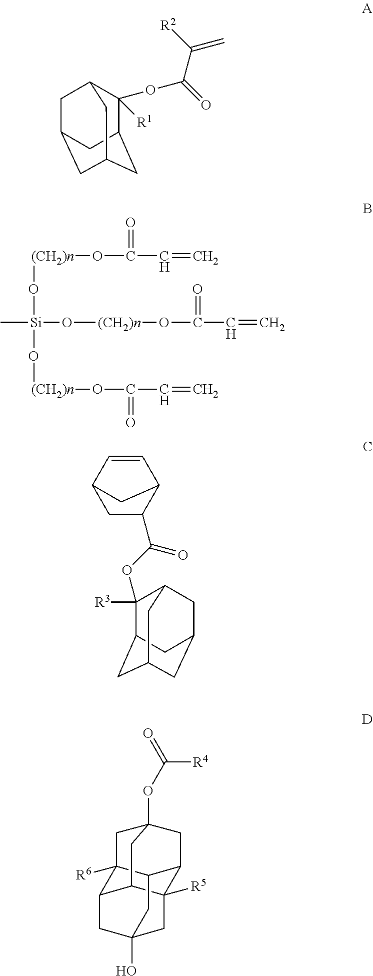

TABLE 1

| | Mono- | Mono- | Mono- | Mono- | | Mw/ |
|---|---|---|---|---|---|---|
| No. | mer A | mer B | mer C | mer D | Mw | Mn |
| Resin 1 | 42.5 | 5 | 1.25 | 1.25 | 6873 | 2 |
| Resin 2 | 45 | 4 | 0.5 | 0.5 | 9209 | 1.8 |
| Resin 3 | 45 | 4 | 0.25 | 0.75 | 7199 | 2 |
| Resin 4 | 45 | 2.5 | 1.25 | 1.25 | 5956 | 1.9 |
| Resin 5 | 42.5 | 4 | 1.75 | 1.75 | 6577 | 2 |
| Resin 6 | 46 | 2.5 | 0.75 | 0.75 | 5516 | 1.5 |
| Comparative resin 1 | 45 | 4 | 0.5 | 0 | 5620 | 1.8 |
| Comparative resin 2 | 45 | 0 | 0.5 | 0.5 | 6530 | 2 |
| Comparative resin 3 | 0 | 4 | 0.5 | 0.5 | 8900 | 1.7 |
| Comparative resin 4 | 39 | 4 | 0.5 | 0.5 | 5747 | 1.6 |
| Comparative resin 5 | 50 | 4 | 0.5 | 0.5 | 5822 | 1.9 |
| Comparative resin 6 | 45 | 0.4 | 0.5 | 0.5 | 8552 | 2 |

### Examples 7 to 28 and Comparative Examples 7 to 23: Preparation of Photoresists 1 to 21 and Comparative Photoresists 1 to 16

The raw materials for the photoresists 1 to 21 of the present disclosure and the comparative photoresists are listed in Table 2

According to the formulations shown in Table 3, the solid components were added to the liquid components and stirred until homogenous. The mixture was filtered through a filter with a pore size of 0.2 μm to prepare the photoresists 1 to 21 and comparative photoresists 1 to 16 in solution form.

TABLE 2

| Resin | Resins 1 to 8 and comparative resins 1 to 8 | |
|---|---|---|
| Photoacid generator | 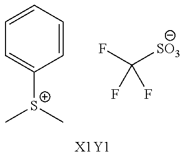 | 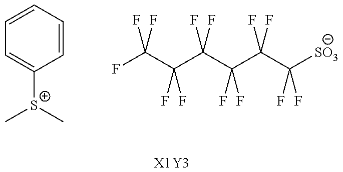 |
| | 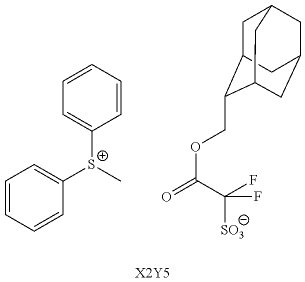 | 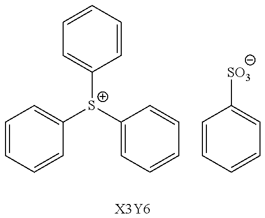 |
| | 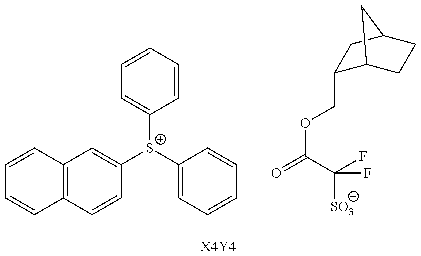 | |
| | 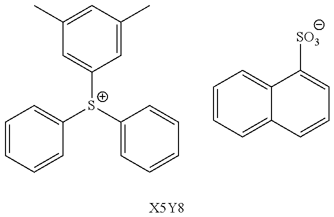 | 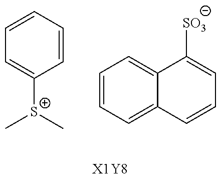 |

| | |
|---|---|
| | 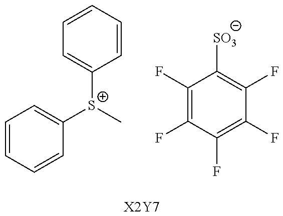 |
| Solvent | cyclohexanone (S1), ethylene glycol monoethyl ether (S2), and γ-butyrolactone (S3) |
| Quencher | 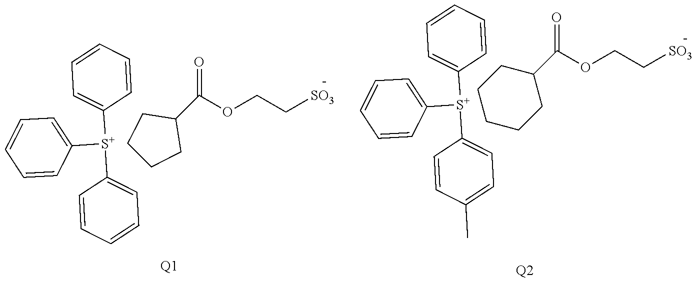 |
| Surfactant | KH-20, KH-30 |

TABLE 3

| | Resin | | Photoacid generator | | Solvent | | Quencher | | Surfactant | |
|---|---|---|---|---|---|---|---|---|---|---|
| | Type | Amount/g | Type | Amount/g | Type | Amount/g | Type | Amount/g | Type | Amount/g |
| Photoresist 1 | Resin 1 | 85 | X1Y1 | 7 | S1 | 1,500 | Q1 | 2 | KH-30 | 0.15 |
| (P1) | | | | | | | | | | |
| Photoresist 2 | Resin 1 | 75 | X1Y1 | 1 | S1 | 1000 | Q1 | 0.5 | KH-30 | 0.1 |
| (P2) | | | | | | | | | | |
| Photoresist 3 | Resin 1 | 80 | X1Y1 | 3 | S1 | 1200 | Q1 | 0.8 | KH-30 | 0.12 |
| (P3) | | | | | | | | | | |
| Photoresist 4 | Resin 1 | 90 | X1Y1 | 5 | S1 | 1600 | Q1 | 1.5 | KH-30 | 0.16 |
| (P4) | | | | | | | | | | |
| Photoresist 5 | Resin 1 | 95 | X1Y1 | 10 | S1 | 2000 | Q1 | 3 | KH-30 | 0.2 |
| (P5) | | | | | | | | | | |
| Photoresist 6 | Resin 1 | 85 | X1Y3 | 7 | S1 | 1,500 | Q1 | 2 | KH-30 | 0.15 |
| (P6) | | | | | | | | | | |
| Photoresist 7 | Resin 1 | 85 | X2Y5 | 7 | S1 | 1,500 | Q1 | 2 | KH-30 | 0.15 |
| (P7) | | | | | | | | | | |
| Photoresist 8 | Resin 1 | 85 | X3Y6 | 7 | S1 | 1,500 | Q1 | 2 | KH-30 | 0.15 |
| (P8) | | | | | | | | | | |
| Photoresist 9 | Resin 1 | 85 | X4Y4 | 7 | S1 | 1,500 | Q1 | 2 | KH-30 | 0.15 |
| (P9) | | | | | | | | | | |
| Photoresist 10 | Resin 1 | 85 | X5Y8 | 7 | S1 | 1,500 | Q1 | 2 | KH-30 | 0.15 |
| (P10) | | | | | | | | | | |
| Photoresist 11 | Resin 1 | 85 | X1Y8 | 7 | S1 | 1,500 | Q1 | 2 | KH-30 | 0.15 |
| (P11) | | | | | | | | | | |
| Photoresist 12 | Resin 1 | 85 | X2Y7 | 7 | S1 | 1,500 | Q1 | 2 | KH-30 | 0.15 |
| (P12) | | | | | | | | | | |
| Photoresist 13 | Resin 1 | 85 | X1Y1 | 7 | S2 | 1,500 | Q1 | 2 | KH-30 | 0.15 |
| (P13) | | | | | | | | | | |
| Photoresist 14 | Resin 1 | 85 | X1Y1 | 7 | S3 | 1,500 | Q1 | 2 | KH-30 | 0.15 |
| (P14) | | | | | | | | | | |
| Photoresist 15 | Resin 1 | 85 | X1Y1 | 7 | S1 | 1,500 | Q2 | 2 | KH-30 | 0.15 |
| (P15) | | | | | | | | | | |
| Photoresist 16 | Resin 1 | 85 | X1Y1 | 7 | S1 | 1,500 | Q1 | 2 | KH-20 | 0.15 |
| (P16) | | | | | | | | | | |
| Photoresist 17 | Resin 2 | 85 | X1Y1 | 7 | S1 | 1,500 | Q1 | 2 | KH-30 | 0.15 |
| (P17) | | | | | | | | | | |
| Photoresist 18 | Resin 3 | 85 | X1Y1 | 7 | S1 | 1,500 | Q1 | 2 | KH-30 | 0.15 |
| (P18) | | | | | | | | | | |
| Photoresist 19 | Resin 4 | 85 | X1Y1 | 7 | S1 | 1,500 | Q1 | 2 | KH-30 | 0.15 |
| (P19) | | | | | | | | | | |
| Photoresist 20 | Resin 5 | 85 | X1Y1 | 7 | S1 | 1,500 | Q1 | 2 | KH-30 | 0.15 |
| (P20) | | | | | | | | | | |
| Photoresist 21 | Resin 6 | 85 | X1Y1 | 7 | S1 | 1,500 | Q1 | 2 | KH-30 | 0.15 |
| (P21) | | | | | | | | | | |
| Comparative | Comparative | 85 | X1Y1 | 7 | S1 | 1,500 | Q1 | 2 | KH-30 | 0.15 |
| photoresist 1 | resin 1 | | | | | | | | | |
| (CP1) | | | | | | | | | | |
| Comparative | Comparative | 80 | X1Y1 | 3 | S1 | 1200 | Q1 | 0.8 | KH-30 | 0.12 |
| photoresist 2 | resin 2 | | | | | | | | | |
| (CP2) | | | | | | | | | | |
| Comparative | Comparative | 90 | X1Y1 | 5 | S1 | 1600 | Q1 | 1.5 | KH-30 | 0.16 |
| photoresist 3 | resin 3 | | | | | | | | | |
| (CP3) | | | | | | | | | | |
| Comparative | Comparative | 95 | X1Y1 | 10 | S1 | 2000 | Q1 | 3 | KH-30 | 0.2 |
| photoresist 4 | resin 4 | | | | | | | | | |
| (CP4) | | | | | | | | | | |
| Comparative | Comparative | 85 | X1Y3 | 7 | S1 | 1,500 | Q1 | 2 | KH-30 | 0.15 |
| photoresist 5 | resin 5 | | | | | | | | | |
| (CP5) | | | | | | | | | | |
| Comparative | Comparative | 85 | X3Y6 | 7 | S1 | 1,500 | Q1 | 2 | KH-30 | 0.15 |
| photoresist 6 | resin 6 | | | | | | | | | |
| (CP6) | | | | | | | | | | |
| Comparative | Comparative | 85 | X1Y1 | 7 | S2 | 1,500 | Q1 | 2 | KH-30 | 0.15 |
| photoresist 7 | resin 2 | | | | | | | | | |
| (CP7) | | | | | | | | | | |
| Comparative | Comparative | 85 | X1Y1 | 7 | S3 | 1,500 | Q1 | 2 | KH-30 | 0.15 |
| photoresist 8 | resin 2 | | | | | | | | | |
| (CP8) | | | | | | | | | | |
| Comparative | Comparative | 85 | X1Y1 | 7 | S1 | 1,500 | Q2 | 2 | KH-30 | 0.15 |
| photoresist 9 | resin 2 | | | | | | | | | |
| (CP9) | | | | | | | | | | |
| Comparative | Comparative | 85 | X1Y1 | 7 | S1 | 1,500 | Q1 | 2 | KH-20 | 0.15 |
| photoresist 10 | resin 3 | | | | | | | | | |
| (CP10) | | | | | | | | | | |
| Comparative | Comparative | 85 | X1Y1 | 7 | S1 | 1,500 | Q1 | 2 | KH-30 | 0.15 |
| photoresist 11 | resin 3 | | | | | | | | | |
| (CP11) | | | | | | | | | | |
| Comparative | Comparative | 85 | X1Y1 | 7 | S1 | 1,500 | Q1 | 2 | KH-30 | 0.15 |
| photoresist 12 | resin 3 | | | | | | | | | |
| (CP12) | | | | | | | | | | |
| Comparative | Comparative | 85 | X1Y1 | 7 | S1 | 1,500 | Q1 | 2 | KH-30 | 0.15 |
| photoresist 13 | resin 4 | | | | | | | | | |
| (CP13) | | | | | | | | | | |
| Comparative | Comparative | 85 | X1Y1 | 7 | S1 | 1,500 | Q1 | 2 | KH-30 | 0.15 |
| photoresist 14 | resin 4 | | | | | | | | | |
| (CP14) | | | | | | | | | | |
| Comparative | Comparative | 85 | X1Y1 | 7 | S1 | 1,500 | Q1 | 2 | KH-30 | 0.15 |
| photoresist 15 | resin 5 | | | | | | | | | |
| (CP15) | | | | | | | | | | |
| Comparative | Comparative | 85 | X1Y1 | 7 | S1 | 1,500 | Q1 | 2 | KH-30 | 0.15 |
| photoresist 16 | resin 6 | | | | | | | | | |
| (CP16) | | | | | | | | | | |

### Application and Effect Examples

ArF dry lithography pattern test (hole pattern test)

### 1. Hole Pattern Formation:

On a substrate (silicon wafer), a carbon film ODL-70 (carbon content: 65 wt %, Shin-Etsu Chemical Co., Ltd.) was deposited to a thickness of 200 nm, and on top of it, a silicon-containing spin-on hard mask SHB-A940 (silicon content: 43 weight %; Shin-Etsu Chemical Co., Ltd.) is deposited to a thickness of 35 nm. Then, a photoresist composition was spin-coated on top, followed by baking on a hotplate at 200° C. for 60 seconds to form a 100 nm thick photoresist layer.

Exposure was carried out in an ArF excimer laser stepper (Nikon Corp., NA-0.68). The photoresist layer was baked (PEB) at 95° C. for 60 seconds. After PEB, the developer listed in Table 4 was injected from the developer nozzle while the wafer was spun at 30 rpm for 3 seconds, followed by a static soak development for 27 seconds. A pattern of holes with 100 nm spacing was formed.

### 2. Photosensitivity Evaluation:

The hole pattern formed as described above was observed under a TD-SEM (CG-4000, Hitachi High-Technologies Corp.). The optimal dose (Eop) is the exposure dose (mJ/cm²) that provides a hole diameter of 50 nm at 100 nm spacing and is used as an index for photosensitivity.

### 3. Depth of Focus (DOF) Margin Evaluation:

The hole size at the optimal dose was measured under TD-SEM (CG-4000), and the DOF margin providing a size of 50 nm±5 nm was determined. A larger value indicates smaller changes in pattern size with changes in DOF, and therefore, a better DOF margin.

### 4. CDU Evaluation:

The hole pattern formed as described was observed under TD-SEM (CG-4000), and the diameters of 125 holes were measured. The triple value (30) of the standard deviation (c) was calculated and recorded as CDU. A smaller value of 30 indicates a smaller deviation of the hole.

### 5. PPD Evaluation:

After PEB (with no delay, PPD-Oh), the wafer was immediately developed by suspension immersion for 30 seconds to form a hole pattern with a diameter of 50 nm and a spacing of 100 nm. In another operation, the wafer was kept for 6 hours (PPD=6 hours) after PEB, and then it was similarly developed to form a pattern.

The hole patterns at PPD-Oh and 6 h were observed under TD-SEM (CG-4000), and the diameters of 125 holes were measured. The average value was taken as the hole size (CD), and CDU was calculated using the same method as above. The difference between the CD at PPD Oh and the CD at PPD 6 h was taken as the CD shrinkage caused by PPD (APPD CD).

The effects of the photoresists PI to P21 prepared in Examples 7 to 28 and the photoresists CP1 to CP16 prepared in Comparative Examples 7 to 23 are shown in Table 4.

The developers used in Table 4 are butyl acetate (D-1), 2-heptanone (D-2), and methyl benzoate (D-3).

TABLE 4

| | | | | | | CD | CDU | CD | CDU | |
|---|---|---|---|---|---|---|---|---|---|---|
| | PEB | | | | | (nm) | (3σ, m) | (nm) | (3σ, nm) | ΔPPD |
| Photoresist | temperature | | Eop | DOF | CDU | At PPD | At PPD | at PPD | At PPD | CD |
| No. | (° C.) | Developer | (mJ/cm²) | (nm) | (nm) | 0 h | 0 h | 6 h | 6 h | (nm) |
| P1 | 90 | Butyl acetate | 28.4 | 100 | 3.3 | 46.5 | 5 | 44.4 | 5.1 | 2.1 |
| P2 | 95 | Butyl acetate | 27.4 | 90 | 3.5 | 48.1 | 6.4 | 46.7 | 6.7 | 1.4 |
| P3 | 100 | Butyl acetate | 33.3 | 110 | 3.3 | 52.5 | 5.1 | 50.9 | 5.4 | 1.6 |
| P4 | 90 | Butyl acetate | 33.3 | 90 | 3.7 | 52.2 | 5.8 | 49.6 | 6 | 2.6 |
| P5 | 95 | Butyl acetate | 38.6 | 100 | 3.9 | 53.2 | 5.4 | 51.2 | 5.6 | 2 |
| P6 | 100 | 2-Heptanone | 34 | 120 | 3.1 | 45.2 | 5 | 43.5 | 5.2 | 1.7 |
| P7 | 90 | Butyl acetate | 38.2 | 90 | 3.8 | 44.6 | 6.3 | 42.5 | 6.5 | 2.1 |
| P8 | 95 | Butyl acetate | 35.3 | 100 | 3.5 | 49.9 | 5.3 | 48.3 | 5.6 | 1.6 |
| P9 | 100 | Butyl acetate | 31.2 | 100 | 3.7 | 40.2 | 6.5 | 38.5 | 6.7 | 1.7 |
| P10 | 90 | Butyl acetate | 30.8 | 90 | 3.9 | 48.4 | 6.5 | 46.3 | 6.6 | 2.1 |
| P11 | 95 | Butyl acetate | 32.1 | 120 | 3.3 | 52.5 | 5.3 | 51.5 | 5.5 | 1 |
| P12 | 100 | Butyl acetate | 31.2 | 110 | 3.8 | 52.5 | 5 | 49.8 | 5.2 | 2.7 |
| P13 | 90 | Butyl acetate | 36.6 | 110 | 3.4 | 53.9 | 5.7 | 51.9 | 6 | 2 |
| P14 | 95 | Butyl acetate | 37.9 | 120 | 3.5 | 53 | 5.5 | 51.4 | 5.8 | 1.6 |
| P15 | 100 | Butyl acetate | 36.8 | 120 | 3 | 45.7 | 5.3 | 42.2 | 5.6 | 3.5 |
| P16 | 90 | Butyl acetate | 33.8 | 110 | 3.6 | 48.5 | 5 | 45.5 | 5.3 | 3 |
| P17 | 95 | 2-Heptanone | 33.4 | 120 | 3.1 | 51.7 | 6.1 | 47.8 | 6.3 | 3.9 |
| P18 | 100 | Butyl acetate | 33.1 | 100 | 3 | 46 | 5.4 | 43 | 5.7 | 3 |
| P19 | 90 | Butyl acetate | 34.9 | 110 | 3.2 | 41.6 | 5 | 38.2 | 5.1 | 3.4 |
| P20 | 95 | Butyl acetate | 27.7 | 100 | 3.5 | 53.2 | 6.4 | 49.3 | 6.5 | 3.9 |
| P21 | 95 | Methyl benzoate | 32.8 | 90 | 3.3 | 49.4 | 6.5 | 45.5 | 6.7 | 3.9 |
| CP1 | 90 | Butyl acetate | 30.3 | 80 | 4.7 | 49.5 | 6.3 | 44 | 6.6 | 5.5 |
| CP2 | 100 | Butyl acetate | 35.5 | 70 | 5.9 | 54.2 | 6.5 | 47.3 | 6.8 | 6.9 |
| CP3 | 90 | Butyl acetate | 28.2 | 50 | 5.6 | 42.3 | 5.1 | 37.3 | 5.3 | 5 |
| CP4 | 95 | Butyl acetate | 38.1 | 80 | 5.9 | 52 | 6.1 | 47.7 | 6.3 | 4.3 |
| CP5 | 100 | 2-Heptanone | 35.9 | 70 | 6 | 47.8 | 6.4 | 41.9 | 6.7 | 5.9 |
| CP6 | 95 | Butyl acetate | 38 | 70 | 5.3 | 47 | 5.5 | 41.4 | 5.6 | 5.6 |
| CP7 | 90 | Butyl acetate | 28.9 | 50 | 5.5 | 46.6 | 6.4 | 40.1 | 6.7 | 6.5 |
| CP8 | 95 | Butyl acetate | 36.8 | 70 | 5 | 49.8 | 6.1 | 43.5 | 6.3 | 6.3 |
| CP9 | 100 | Butyl acetate | 32.6 | 50 | 4.4 | 42.1 | 5.6 | 36.8 | 5.7 | 5.3 |
| CP10 | 90 | Butyl acetate | 27.1 | 60 | 5.7 | 48.2 | 5 | 42.4 | 5.1 | 5.8 |
| CP11 | 95 | 2-Heptanone | 34.1 | 70 | 5.8 | 47.9 | 5.9 | 43.2 | 6.1 | 4.7 |
| CP12 | 100 | Butyl acetate | 30.3 | 50 | 4.4 | 54.2 | 5.4 | 47.6 | 5.7 | 6.6 |
| CP13 | 90 | Butyl acetate | 38.1 | 60 | 4.4 | 41.6 | 5.1 | 35.4 | 5.4 | 6.2 |
| CP14 | 95 | Butyl acetate | 33.3 | 50 | 4.5 | 41.9 | 5.4 | 36.6 | 5.7 | 5.3 |
| CP15 | 100 | Butyl acetate | 29.5 | 60 | 5.1 | 42.3 | 5.6 | 35.9 | 5.7 | 6.4 |
| CP16 | 95 | Methyl benzoate | 32.7 | 80 | 5.9 | 46.7 | 5.4 | 40 | 5.6 | 6.7 |

As can be seen from the table above, the photoresist compositions within the scope of the present disclosure, compared with the comparative photoresist compositions, show improvements in DOF and CDU, and a reduction in CD shrinkage caused by PPD (i.e., smaller CD changes). Especially, the photoresist containing resin 1 of the present disclosure, compared with photoresists formed by resins 2-6, exhibits a significantly reduced critical dimension (CD) shrinkage.

1. A resin, wherein the resin is obtained by polymerizing the following monomers in parts by weight: 40 to 47.5 parts of monomer A, 0.5 to 5 parts of monomer B, 0.25 to 2.5 parts of monomer C, and 0.25 to 2.5 parts of monomer D; 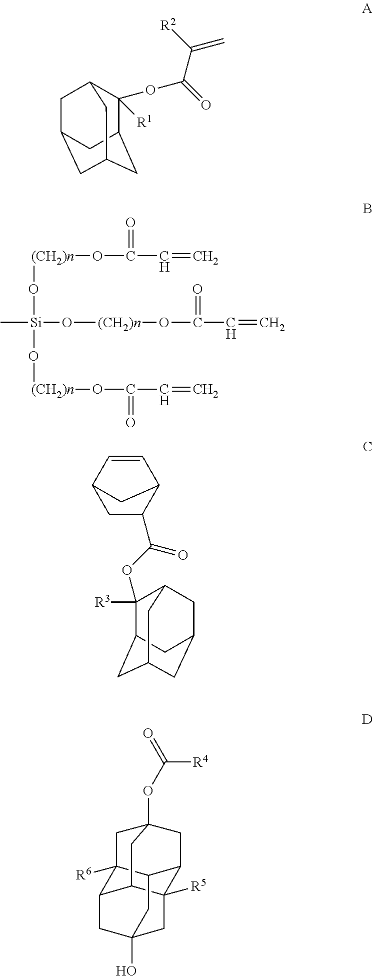
wherein R¹ is C₁₋₁₀ alkyl;
R² is H or C₁₋₁₀ alkyl;
n is 1, 2, or 3;
R³ is C₁₋₁₀ alkyl;
R⁴ is C₂₋₄ alkenyl;
R⁵ and R⁶ are independently H or C₁₋₅ alkyl;
the molecular weight distribution coefficient (Mw/Mn) of the resin is 1.5 to 2.0.

2. The resin according to claim 1, wherein the resin meets one or more than one of the following conditions:
(1) for R¹, the C₁₋₁₀ alkyl is C₁₋₅ alkyl;
(2) for R², the C₁₋₁₀ alkyl is C₁₋₅ alkyl;
(3) for R³, the C₁₋₁₀ alkyl is C₁₋₅ alkyl;
(4) for R⁴, the C₂₋₄ alkenyl is C₂₋₃ alkenyl;
(5) for R⁵, the C₁₋₅ alkyl is methyl, ethyl, n-propyl, isopropyl, n-butyl, sec-butyl, isobutyl, or tert-butyl.

3. The resin according to claim 2, wherein the resin meets one or more than one of the following conditions:
(1) for R¹, the C₁₋₁₀ alkyl is methyl, ethyl, n-propyl, isopropyl, n-butyl, sec-butyl, isobutyl, or tert-butyl;
(2) for R², the C₁₋₁₀ alkyl is methyl, ethyl, n-propyl, isopropyl, n-butyl, sec-butyl, isobutyl, or tert-butyl;
(3) for R³, the C₁₋₁₀ alkyl is methyl, ethyl, n-propyl, isopropyl, n-butyl, sec-butyl, isobutyl, or tert-butyl;
(4) for R⁴, the C₂₋₄ alkenyl is ethenyl or isopropenyl;
(5) for R⁵, the C₁₋₅ alkyl is methyl.

4. The resin according to claim 1, wherein the resin meets one or more than one of the following conditions:
(1) the monomer A is 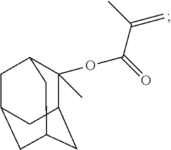 [SMILES: C=C(C)C(=O)OC1(C)C2CC3CC(C2)CC1C3]
(2) the monomer B is 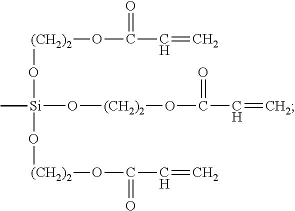
(3) the monomer C is 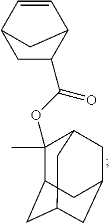 [SMILES: CC1(OC(=O)C2CC3C=CC2C3)C2CC3CC(C2)CC1C3]
(4) the monomer D is 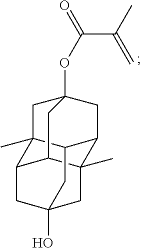 [SMILES: C=C(C)C(=O)OC12CC3C4CC5(O)CC(C(C1)C3(C)C5)C4(C)C2]
(5) the monomer A is 42.5 to 46 parts by weight;
(6) the monomer B is 2.5 to 5 parts by weight;
(7) the monomer C is 0.25 to 1.75 parts by weight;
(8) the monomer D is 0.5 to 1.75 parts by weight;
(9) the weight-average molecular weight of the resin is 5,000 to 10,000;
(10) the molecular weight distribution coefficient of the resin is 1.8 to 2.0.

5. The resin according to claim 4, wherein the resin meets one or more than one of the following conditions:
(1) the monomer A is 45 parts by weight;
(2) the monomer B is 4 parts by weight;
(3) the monomer C is 0.75, or 1.25 parts by weight;
(4) the monomer D is 0.75 parts by weight;
(5) the weight-average molecular weight of the resin is 5,516 to 9,209.

6. The resin according to claim 1, wherein the monomer A is 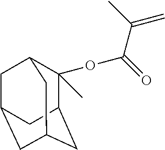 [SMILES: C=C(C)C(=O)OC1(C)C2CC3CC(C2)CC1C3]
and is 42.5 to 46 parts by weight;
The monomer B is 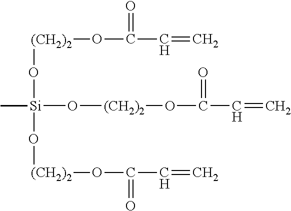
and is 2.5 to 5 parts by weight;
the monomer C is 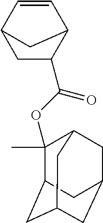 [SMILES: CC1(OC(=O)C2CC3C=CC2C3)C2CC3CC(C2)CC1C3]
and is 0.25 to 1.25 parts by weight;
the monomer D is 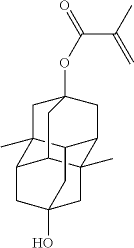 [SMILES: C=C(C)C(=O)OC12CC3C4CC5(O)CC(C(C1)C3(C)C5)C4(C)C2]
and is 0.5 to 1.75 parts by weight.

7. The resin according to claim 1, wherein the resin is any one of resins 1 to 6 obtained by polymerizing the following monomers in parts by weight:
resin 1: 42.5 parts of monomer A, 5 parts of monomer B, 1.25 parts of monomer C, and 1.25 parts of monomer D; with a weight-average molecular weight of 6,873 and a molecular weight distribution coefficient of 2;
resin 2: 45 parts of monomer A, 4 parts of monomer B, 0.5 parts of monomer C, and 0.5 parts of monomer D; with a weight-average molecular weight of 9209 and a molecular weight distribution coefficient of 1.8;
resin 3: 45 parts of monomer A, 4 parts of monomer B, 0.25 parts of monomer C, and 0.75 parts of monomer D; with a weight-average molecular weight of 7199 and a molecular weight distribution coefficient of 2;
resin 4: 45 parts of monomer A, 2.5 parts of monomer B, 1.25 parts of monomer C, and 1.25 parts of monomer D; with a weight-average molecular weight of 5956 and a molecular weight distribution coefficient of 1.9;
resin 5: 42.5 parts of monomer A, 4 parts of monomer B, 1.75 parts of monomer C, and 1.75 parts of monomer D; with a weight-average molecular weight of 6577 and a molecular weight distribution coefficient of 2;
resin 6: 46 parts of monomer A, 2.5 parts of monomer B, 0.75 parts of monomer C, and 0.75 parts of monomer D; with a weight-average molecular weight of 5,516 and a molecular weight distribution coefficient of 1.5;
in the resins 1 to 6, the monomer A is 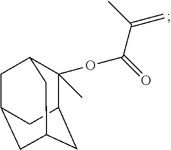 [SMILES: C=C(C)C(=O)OC1(C)C2CC3CC(C2)CC1C3]
the monomer B is 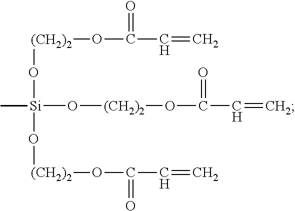
the monomer C is 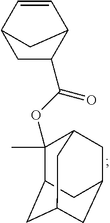 [SMILES: CC1(OC(=O)C2CC3C=CC2C3)C2CC3CC(C2)CC1C3]
the monomer D is

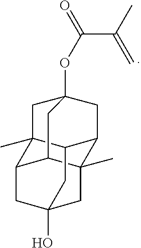 [SMILES: C=C(C)C(=O)OC12CC3C4CC5(O)CC(C(C1)C3(C)C5)C4(C)C2]

8. A preparation method for the resin, wherein the preparation method comprises the following steps: carrying out a polymerization reaction involving the monomer A in 40 to 47.5 parts by weight, the monomer B in 0.5 to 5 parts by weight, the monomer C in 0.25 to 2.5 parts by weight, and the monomer D in 0.25 to 2.5 parts by weight in an organic solvent to obtain the resin; 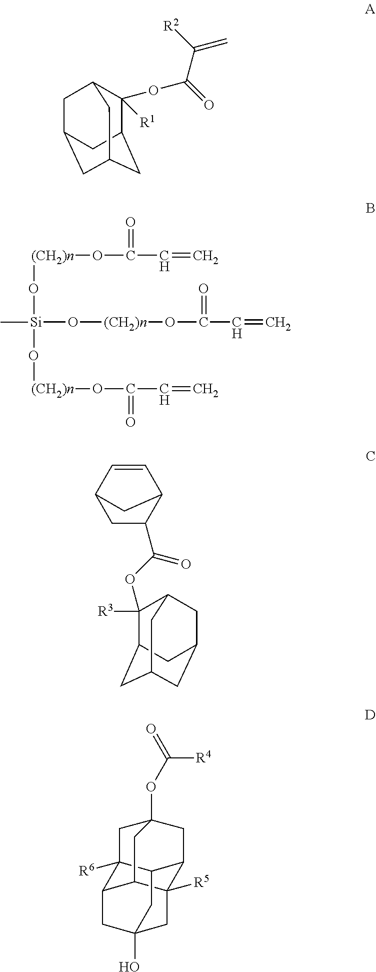
wherein R¹, R², R³, R⁴, R⁵, R⁶, n, the amount of the monomer A, the amount of the monomer B, the amount of the monomer C, and the amount of the monomer D are as defined in claim 1.

9. The preparation method for the resin according to claim 8, wherein the preparation method for the resin meets one or more than one of the following conditions:
(1) in the polymerization reaction, the total weight of the monomer A, the monomer B, the monomer C, and the monomer D to the weight of the organic solvent is in the ratio of 0.46:1 to 1.2:1;
(2) in the polymerization reaction, the organic solvent is one or more than one of aromatic solvents, ether solvents, methyl ethyl ketone, propylene glycol monomethyl ether acetate, and γ-butyrolactone;
(3) the polymerization reaction is initiated in the presence of a free radical initiator or by heating.

10. The preparation method for the resin according to claim 9, wherein the preparation method for the resin meets one or more than one of the following conditions:
(1) in the polymerization reaction, the total weight of the monomer A, the monomer B, the monomer C, and the monomer D to the weight of the organic solvent is in the ratio of 0.50:1, 0.51:1, 0.52:1, or 0.53:1;
(2) in the polymerization reaction, the organic solvent is propylene glycol monomethyl ether acetate;
(3) when the polymerization reaction is initiated by heating, the temperature of the polymerization reaction is 50 to 150° C.

11. A resin obtained by the preparation method for the resin according to claim 9.

12. A photoresist composition, wherein the photoresist composition is prepared from the following raw materials comprising the following components in parts by weight: 75 to 95 parts of a resin, 1.0 to 10 parts of a photoacid generator, 1,000 to 2,000 parts of a solvent, 0.5 to 3.0 part of a quencher, and a surfactant;
the resin is the resin according to claim 1.

13. The photoresist composition according to claim 12, wherein the photoresist composition meets one or more than one of the following conditions:
(1) in the photoresist composition, the resin is 85 to 95 parts by weight;
(2) in the photoresist composition, the resin is resin 1 obtained by polymerizing the following monomers in parts by weight: 42.5 parts of monomer A, 5 parts of monomer B, 1.25 parts of monomer C, and 1.25 parts of monomer D; with a weight-average molecular weight of 6,873 and a molecular weight distribution coefficient of 2; the monomer A is 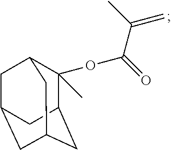 [SMILES: C=C(C)C(=O)OC1(C)C2CC3CC(C2)CC1C3]
the monomer B is 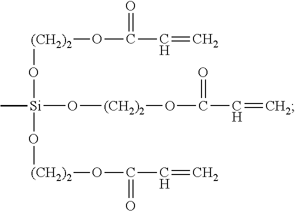
the monomer C is 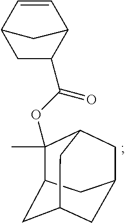 [SMILES: CC1(OC(=O)C2CC3C=CC2C3)C2CC3CC(C2)CC1C3]
the monomer D is 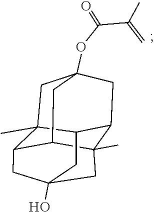 [SMILES: C=C(C)C(=O)OC12CC3C4CC5(O)CC(C(C1)C3(C)C5)C4(C)C2]
(3) in the photoresist composition, the photoacid generator is 3 to 10 parts by weight;
(4) in the photoresist composition, the photoacid generator is the compound of formula (I):
wherein X⁺ is 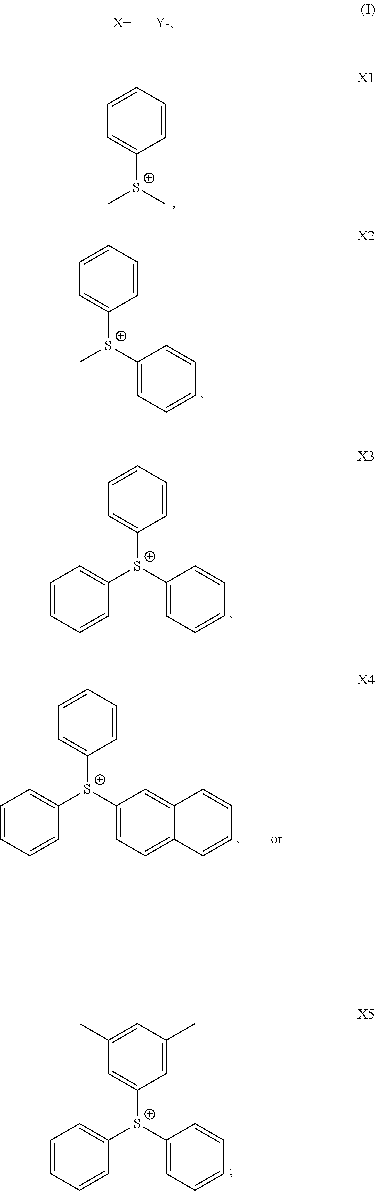
Y⁻ is 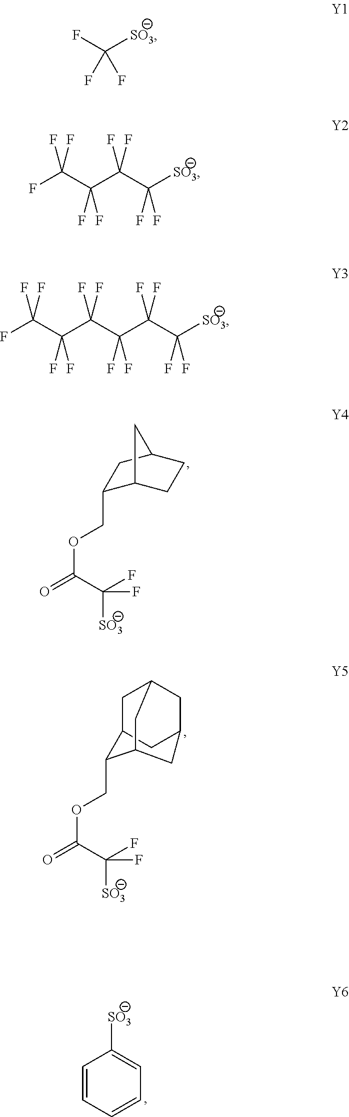 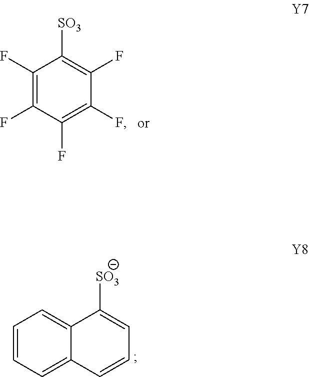
(5) in the photoresist composition, the solvent is 1,200 to 1,600 parts by weight;
(6) in the photoresist composition, the solvent is one or more than one of ketone solvent, monohydric alcohol solvent, dihydric alcohol solvent, ether solvent, and ester solvent;
(7) in the photoresist composition, the quencher is 0.8 to 2 parts by weight;
(8) in the photoresist composition, the quencher is one or more than one of amine compound, sulfonate, and carboxylate;
(9) in the photoresist composition, the surfactant is 0.1 to 0.2 parts by weight;
(10) the surfactant is one or more than one of FC-4430, S-381, E1004, KH-20, and KH-30.

14. The photoresist composition according to claim 13, wherein the photoresist composition meets one or more than one of the following conditions:
(1) in the photoresist composition, the resin is 90 parts by weight;
(2) in the photoresist composition, the photoacid generator is 5 or 7 parts by weight;
(3) in the photoresist composition, the photoacid generator is one or more than one of 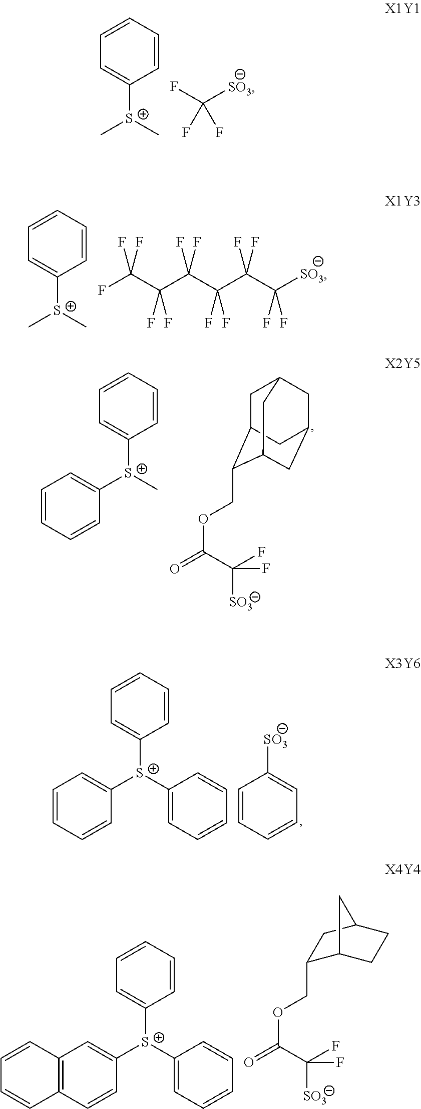 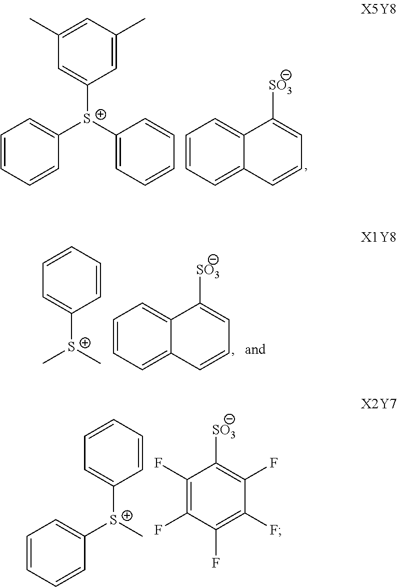
(4) in the photoresist composition, the solvent is 1,500 or 1,600 parts by weight;
(5) in the photoresist composition, the solvent is one or more than one of cyclohexanone, ethylene glycol monoethyl ether, and γ-butyrolactone;
(6) in the photoresist composition, the quencher is 1.5 parts by weight;
(7) in the photoresist composition, the quencher is a compound of formula Q1 or formula Q2; 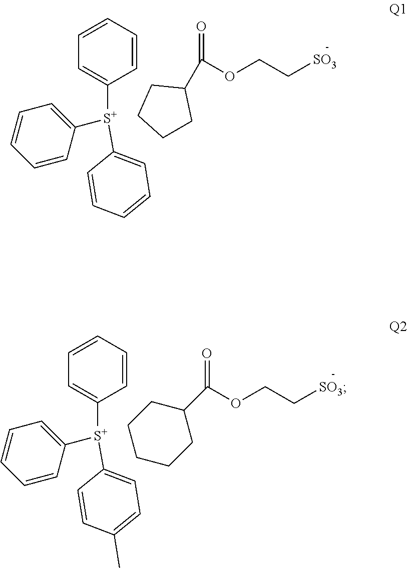
(8) in the photoresist composition, the surfactant is 0.15 parts by weight;
(9) the surfactant is KH-20 or KH-30.

15. The photoresist composition according to claim 12, wherein,
in the photoresist composition, the photoacid generator is one or more than one of 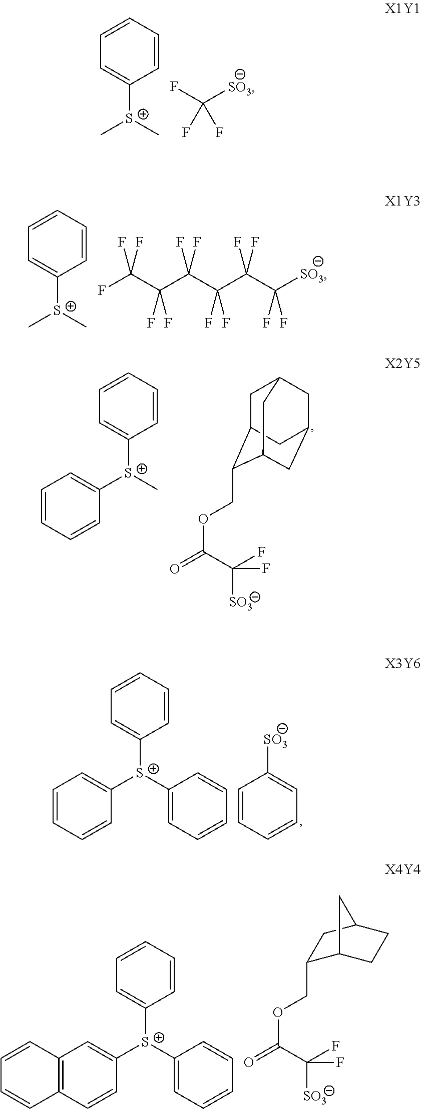 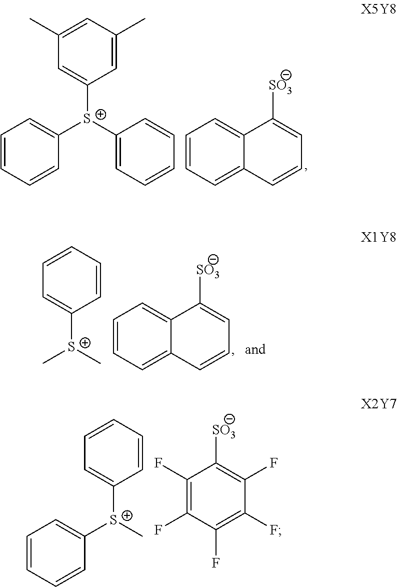
the solvent is one or more than one of cyclohexanone, ethylene glycol monoethyl ether, and γ-butyrolactone;
the quencher is 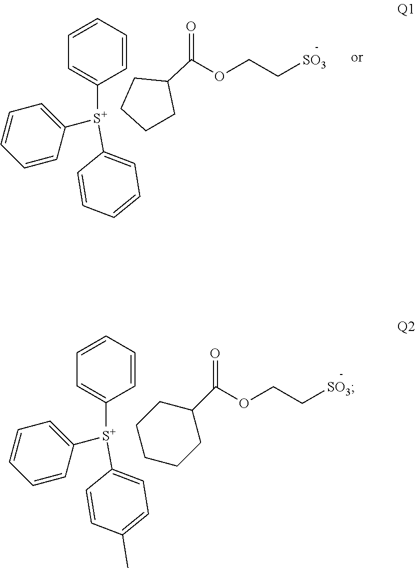
the surfactant is KH-20 or KH-30.

16. The photoresist composition according to claim 15, wherein, the resin is resin 1 obtained by polymerizing the following monomers in parts by weight: 42.5 parts of monomer A, 5 parts of monomer B, 1.25 parts of monomer C, and 1.25 parts of monomer D; with a weight-average molecular weight of 6,873 and a molecular weight distribution coefficient of 2; the monomer A is 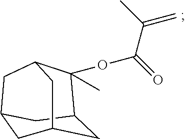 [SMILES: C=C(C)C(=O)OC1(C)C2CC3CC(C2)CC1C3]
the monomer B is 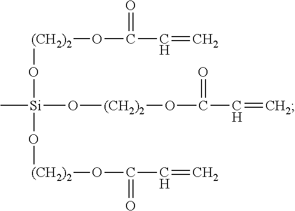
the monomer C is 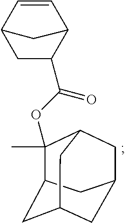 [SMILES: CC1(OC(=O)C2CC3C=CC2C3)C2CC3CC(C2)CC1C3]
the monomer D is 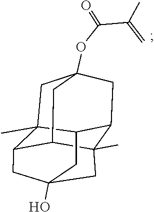 [SMILES: C=C(C)C(=O)OC12CC3C4CC5(O)CC(C(C1)C3(C)C5)C4(C)C2]
the quencher is 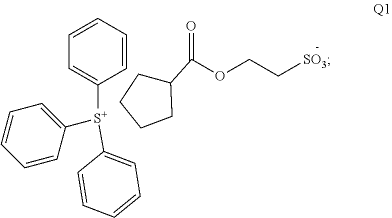
the surfactant is KH-30.

17. The photoresist composition according to claim 12, wherein, the photoresist composition is any one of the photoresist compositions prepared from the following components in parts by weight:
photoresist composition 1: 85 parts of resin 1, 7 parts of the compound of formula X1YI, 1,500 parts of cyclohexanone, 2 parts of the compound of formula Q1, and 0.15 parts of KH-30;
photoresist composition 2: 75 parts of resin 1, 1 part of the compound of formula X1YI, 1000 parts of cyclohexanone, 0.5 parts of the compound of formula Q1, and 0.1 parts of KH-30;
photoresist composition 3: 80 parts of resin 1, 3 parts of the compound of formula X1YI, 1200 parts of cyclohexanone, 0.8 parts of the compound of formula Q1, and 0.12 parts of KH-30;
photoresist composition 4: 90 parts of resin 1, 5 parts of the compound of formula X1YI, 1600 parts of cyclohexanone, 1.5 parts of the compound of formula Q1, and 0.16 parts of KH-30;
photoresist composition 5: 95 parts of resin 1, 10 parts of the compound of formula X1YI, 2000 parts of cyclohexanone, 3 parts of the compound of formula Q1, and 0.2 parts of KH-30;
photoresist composition 6: 85 parts of resin 1, 7 parts of the compound of formula X1Y3, 1,500 parts of cyclohexanone, 2 parts of the compound of formula Q1, and 0.15 parts of KH-30;
photoresist composition 7: 85 parts of resin 1, 7 parts of the compound of formula X2Y5, 1,500 parts of cyclohexanone, 2 parts of the compound of formula Q1, and 0.15 parts of KH-30;
photoresist composition 8: 85 parts of resin 1, 7 parts of the compound of formula X3Y6, 1,500 parts of cyclohexanone, 2 parts of the compound of formula Q1, and 0.15 parts of KH-30;
photoresist composition 9: 85 parts of resin 1, 7 parts of the compound of formula X4Y4, 1,500 parts of cyclohexanone, 2 parts of the compound of formula Q1, and 0.15 parts of KH-30;
photoresist composition 10: 85 parts of resin 1, 7 parts of the compound of formula X5Y8, 1,500 parts of cyclohexanone, 2 parts of the compound of formula Q1, and 0.15 parts of KH-30;
photoresist composition 11: 85 parts of resin 1, 7 parts of the compound of formula X1Y8, 1,500 parts of cyclohexanone, 2 parts of the compound of formula Q1, and 0.15 parts of KH-30;
photoresist composition 12: 85 parts of resin 1, 7 parts of the compound of formula X2Y7, 1,500 parts of cyclohexanone, 2 parts of the compound of formula Q1, and 0.15 parts of KH-30;
photoresist composition 13: 85 parts of resin 1, 7 parts of the compound of formula X1Y1, 1,500 parts of ethylene glycol monoethyl ether, 2 parts of the compound of formula Q1, and 0.15 parts of KH-30;
photoresist composition 14: 85 parts of resin 1, 7 parts of the compound of formula X1Y1, 1,500 parts of γ-butyrolactone, 2 parts of the compound of formula Q1, and 0.15 parts of KH-30;
photoresist composition 15: 85 parts of resin 1, 7 parts of the compound of formula X1Y1, 1,500 parts of cyclohexanone, 2 parts of the compound of formula Q2, and 0.15 parts of KH-30;
photoresist composition 16: 85 parts of resin 1, 7 parts of the compound of formula X1Y1, 1,500 parts of γ-butyrolactone, 2 parts of the compound of formula Q1, and 0.15 parts of KH-20;
photoresist composition 17: 85 parts of resin 2, 7 parts of the compound of formula X1Y1, 1,500 parts of cyclohexanone, 2 parts of the compound of formula Q1, and 0.15 parts of KH-30;
photoresist composition 18: 85 parts of resin 3, 7 parts of the compound of formula X1Y1, 1,500 parts of cyclohexanone, 2 parts of the compound of formula Q1, and 0.15 parts of KH-30;
photoresist composition 19: 85 parts of resin 4, 7 parts of the compound of formula X1Y1, 1,500 parts of cyclohexanone, 2 parts of the compound of formula Q1, and 0.15 parts of KH-30;
photoresist composition 20: 85 parts of resin 5, 7 parts of the compound of formula X1Y1, 1,500 parts of cyclohexanone, 2 parts of the compound of formula Q1, and 0.15 parts of KH-30;
photoresist composition 21: 85 parts of resin 6, 7 parts of the compound of formula X1Y1, 1,500 parts of cyclohexanone, 2 parts of the compound of formula Q1, and 0.15 parts of KH-30;
in photoresist composition 1 to 21, the compound of formula Q1 is 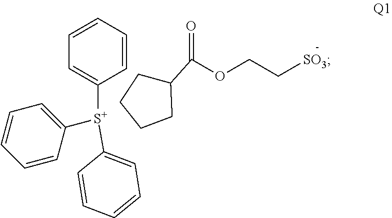
wherein, any one of resins 1 to 6 is obtained by polymerizing the following monomers in parts by weight:
resin 1: 42.5 parts of monomer A, 5 parts of monomer B, 1.25 parts of monomer C, and 1.25 parts of monomer D; with a weight-average molecular weight of 6,873 and a molecular weight distribution coefficient of 2;
resin 2: 45 parts of monomer A, 4 parts of monomer B, 0.5 parts of monomer C, and 0.5 parts of monomer D; with a weight-average molecular weight of 9209 and a molecular weight distribution coefficient of 1.8;
resin 3: 45 parts of monomer A, 4 parts of monomer B, 0.25 parts of monomer C, and 0.75 parts of monomer D; with a weight-average molecular weight of 7199 and a molecular weight distribution coefficient of 2;
resin 4: 45 parts of monomer A, 2.5 parts of monomer B, 1.25 parts of monomer C, and 1.25 parts of monomer D; with a weight-average molecular weight of 5956 and a molecular weight distribution coefficient of 1.9;
resin 5: 42.5 parts of monomer A, 4 parts of monomer B, 1.75 parts of monomer C, and 1.75 parts of monomer D; with a weight-average molecular weight of 6577 and a molecular weight distribution coefficient of 2;
resin 6: 46 parts of monomer A, 2.5 parts of monomer B, 0.75 parts of monomer C, and 0.75 parts of monomer D; with a weight-average molecular weight of 5,516 and a molecular weight distribution coefficient of 1.5;
in the resins 1 to 6, the monomer A is 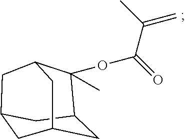 [SMILES: C=C(C)C(=O)OC1(C)C2CC3CC(C2)CC1C3]
the monomer B is 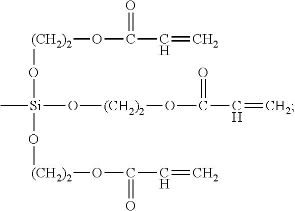
the monomer C is 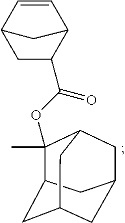 [SMILES: CC1(OC(=O)C2CC3C=CC2C3)C2CC3CC(C2)CC1C3]
the monomer D is

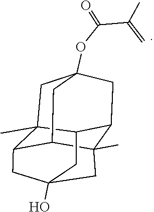 [SMILES: C=C(C)C(=O)OC12CC3C4CC5(O)CC(C(C1)C3(C)C5)C4(C)C2]

18. An ArF dry lithography technology, using the photoresist composition according to claim 12.
